(19) United States
(12) Patent Application Publication
(10) Pub. No.: US 2025/0337218 A1
(43) Pub. Date: Oct. 30, 2025

(54) VERTICAL-CAVITY SURFACE-EMITTING LASER WITH HIGH SIDE-MODE SUPPRESSION RATIO AND HIGH POLARIZATION-MODE SUPPRESSION RATIO AND A METHOD OF MANUFACTURING THE SAME

(71) Applicant: MELLANOX TECHNOLOGIES, LTD., Yokneam (IL)

(72) Inventors: Vladimir IAKOVLEV, Ecublens (CH); Yuri Berk, Kiryat Tivon (IL); Filip Leonard HJORT, Gothenburg (SE); Anders Gösta LARSSON, Hovås (SE); Isabelle CESTIER, Haifa (IL); Elad MENTOVICH, Tel Aviv (IL)

(73) Assignee: MELLANOX TECHNOLOGIES, LTD., Yokneam (IL)

(21) Appl. No.: 18/650,861

(22) Filed: Apr. 30, 2024

(51) Int. Cl. H01S 5/065; H01S 5/068; H01S 5/183

(52) U.S. Cl. CPC H01S 5/0653; H01S 5/06821; H01S 5/18311

(57) ABSTRACT

Some embodiments of the present disclosure are directed to a laser design that provides side-mode suppression that is separately configurable from polarization-mode suppression, such that each may be independently optimized to simultaneously provide a high side-mode suppression ratio and a high polarization-mode suppression ratio. For example, a laser (e.g., a VCSEL) may include an active region configured to emit light, an aperture defining an optical axis, a first element positioned along the optical axis on a first side of the active region, and a second element positioned along the optical axis on a second side of the active region opposite the first side of the active region. The first element may be configured to increase a side-mode suppression ratio of the laser, and the second element may be configured to increase a polarization-mode suppression ratio of the laser.

### TECHNOLOGICAL FIELD

The present disclosure relates to a laser (e.g., a vertical-cavity surface-emitting laser) with a high side-mode suppression ratio and a high polarization-mode suppression ratio.

### BACKGROUND

With demand for high-speed and high-volume data communication increasing, communications providers are increasingly adopting optics-based communication solutions. To meet these demands, high-speed transmitters are being developed.

### GENERAL DESCRIPTION

In one aspect, the present disclosure is directed to a laser, comprising an active region configured to emit light, wherein the active region defines an optical axis; a mode filter positioned along the optical axis on a first side of the active region, wherein the mode filter is configured to increase a side-mode suppression ratio of the laser; and a polarization filter positioned along the optical axis on a second side of the active region opposite the first side of the active region, wherein the polarization filter is configured to increase a polarization-mode suppression ratio of the laser; and wherein the mode filter and the polarization filter are configured to be independently configurable to increase the side-mode suppression ratio of the laser and the polarization-mode suppression ratio of the laser, respectively.

In another aspect, the present disclosure is directed to a vertical-cavity surface-emitting laser (VCSEL) that includes an active region, an aperture, a mode filter, and a polarization filter. The active region may be configured to emit light, and the aperture may be configured for confining electrical current and an optical field of the light. The aperture may define an optical axis. The mode filter may be positioned along the optical axis on a first side of the active region, and the mode filter may be configured to increase a side-mode suppression ratio of the VCSEL. The polarization filter may be positioned along the optical axis on a second side of the active region opposite the first side of the active region, and the polarization filter may be configured to increase a polarization-mode suppression ratio of the VCSEL. The mode filter and the polarization filter may be configured to be independently configurable to increase the side-mode suppression ratio of the VCSEL and the polarization-mode suppression ratio of the VCSEL, respectively.

In some embodiments, the mode filter may have a cross-sectional area in a plane perpendicular to the optical axis, where the cross-sectional area defines a non-circular shape. The amount of non-circularity may be performed by different planar shapes such as ellipses, rectangles, rhombs or any other out of circles. The non-circularity of the mode filter may include different kinds of asymmetrical in-plane lateral shapes for optical filtering of lateral modes and polarization enabling to increase the polarization-mode suppression ratio.

In some embodiments, the VCSEL may include a mirror region positioned along the optical axis on the second side of the active region, where the polarization filter is formed in the mirror region.

In some embodiments, a width of the polarization filter in a direction perpendicular to the optical axis may be greater than a width of the mode filter in the direction perpendicular to the optical axis.

In some embodiments, the active region may include an active material having a refractive index n, where the active region is configured to emit light having a wavelength λ, and where the polarization filter is an etched grating with a period p that is less than λ/n or higher than λ/n.

In some embodiments, the aperture may be configured for confining the electrical current and the optical field of the light via lateral oxidation.

In some embodiments, the aperture may be configured for confining the electrical current and the optical field of the light via a buried tunnel junction.

In some embodiments, a width of the mode filter in a direction perpendicular to the optical axis may be less than a width of the aperture in the direction perpendicular to the optical axis.

In some embodiments, a width of the polarization filter in a direction perpendicular to the optical axis may be greater than a width of the aperture in the direction perpendicular to the optical axis.

In some embodiments, the aperture may have a cross-sectional area in a plane perpendicular to the optical axis, where the cross-sectional area defines a non-circular shape. The amount of non-circularity may be performed by different planar shapes such as ellipses, rectangles, rhombs or any other out of circles. The non-circular shape may be fabricated using non-circular mesa for oxidation or fabricating a non-circular buried tunnel junction aperture.

In some embodiments, the VCSEL may be configured to emit light having a wavelength between about 400 nanometers and 1,600 nanometers.

In another aspect, the present disclosure is directed to a vertical-cavity surface-emitting laser (VCSEL) that includes an active region, an aperture and a mode filter. The active region may be configured to emit light, and the aperture may be configured for confining electrical current and an optical field of the light. The aperture may define an optical axis. The mode filter may be positioned along the optical axis, and the mode filter may be configured to increase a side-mode suppression ratio of the VCSEL. The aperture may have a cross-sectional area in a plane perpendicular to the optical axis, where the cross-sectional area defines a non-circular shape. The mode filter may have a cross-sectional area in a plane perpendicular to the optical axis, where the cross-sectional area defines a non-circular shape. The mode filter, the non-circular shape of the aperture, the non-circular shape of the mode filter, the orientation of the non-circular shape of the aperture, and/or the orientation of the non-circular shape of the mode filter may be configured to be independently configurable to increase the side-mode suppression ratio of the VCSEL and the polarization-mode suppression ratio of the VCSEL. In some embodiments, the mode filter may be configured to increase the side-mode suppression ratio of the VCSEL, and the orientation of the non-circular shape of the aperture may be configured to increase the polarization-mode suppression ratio of the VCSEL independently from the configuration of the mode filter. For example, the orientation of the non-circular shape of the aperture and/or the mode filter may be selected such that a major axis, longest dimension, and/or the like is parallel to a crystallographic axis and/or an inherent polarization direction of a substrate on which one or more layers of the VCSEL are formed.

In another aspect, the present disclosure is directed to a method of manufacturing a vertical-cavity surface-emitting laser (VCSEL). The method may include providing an active region configured to emit light and forming an aperture proximate a first side of the active region, where the aperture is configured for confining electrical current and an optical field of the light, and where the aperture defines an optical axis. The method may include forming a mode filter on the first side of the active region along the optical axis and forming a polarization filter along the optical axis on a second side of the active region opposite the first side of the active region. The mode filter and the polarization filter may be configured to be independently configurable to increase a side-mode suppression ratio of the VCSEL and a polarization-mode suppression ratio of the VCSEL, respectively.

In some embodiments, the method may include forming a layer structure on a first substrate, where the layer structure includes a first mirror region proximate the first substrate, the active region, and a second mirror region. Additionally, or alternatively, the method may include forming the polarization filter on the second mirror region along the optical axis. In some embodiments, the method may include transferring the layer structure to a second substrate such that the polarization filter and the second mirror region are proximate the second substrate and removing the first substrate from the layer structure.

In some embodiments, the method may include selecting a shape and orientation of the aperture to achieve a target polarization-mode suppression ratio, where forming the aperture includes forming the aperture to have the selected shape and the selected orientation.

In some embodiments, the method may include selecting a shape and orientation of the aperture to achieve a target polarization-mode suppression ratio and a target side-mode suppression ratio, where forming the aperture includes forming the aperture to have the selected shape and the selected orientation.

In some embodiments, the method may include selecting a shape, orientation, and alignment of the polarization filter to achieve a target polarization-mode suppression ratio, where forming the polarization filter includes forming the polarization filter to have the selected shape, the selected orientation, and the selected alignment.

In some embodiments, the VCSEL may be one of a plurality of VCSELs in an array, and the method may include selecting, for each VCSEL in the array, a target polarization orientation, where at least two VCSELs in the array have different selected target polarization orientations, and forming, for each VCSEL in the array, at least one of an aperture or a polarization filter to achieve the selected target polarization orientation for the given VCSEL.

In some embodiments, the method may include forming a layer structure on a first substrate, where the layer structure includes the active region, and where the first substrate has a crystallographic axis, and selecting a shape and an orientation of the aperture to align with the crystallographic axis and to increase a polarization-mode suppression ratio and to achieve a target side-mode suppression ratio, where forming the aperture includes forming the aperture to have the selected shape and the selected orientation.

In another aspect, the present invention is directed to a laser including an active region configured to emit light substantially parallel to an optical axis. The laser may include a first element positioned along the optical axis, where the first element is configured to increase a side-mode suppression ratio of the laser. The laser may include a second element positioned along the optical axis, where the second element is configured to increase a polarization-mode suppression ratio of the laser. The first element and the second element may be configured to be independently adjustable to increase the side-mode suppression ratio of the laser and the polarization-mode suppression ratio of the laser, respectively.

In some embodiments, the active region may include an active material, and the second element may be oriented along a direction of highest gain in the active material.

In some embodiments, the laser may have an inherent polarization plane due to spatial anisotropy, and the second element may be oriented along the inherent polarization plane.

In some embodiments, the first element may include a mode filter, and the second element may include a polarization filter.

In some embodiments, the first element may include a mode filter, and the second element may include an aperture. Additionally, or alternatively, the aperture may have a cross-sectional area in a plane perpendicular to the optical axis, where the cross-sectional area of the aperture defines a non-circular shape. In some embodiments, the mode filter may have a cross-sectional area in a plane perpendicular to the optical axis, where the cross-sectional area of the mode filter defines a non-circular shape.

In some embodiments, the second element may include a polarization filter and an aperture having a cross-sectional area in a plane perpendicular to the optical axis, where the cross-sectional area of the aperture defines a non-circular shape.

In some embodiments, the second element may include a polarization filter and a mode filter having a cross-sectional area in a plane perpendicular to the optical axis, where the cross-sectional area of the mode filter defines a non-circular shape.

In some embodiments, the second element may include a polarization filter, a mode filter having a cross-sectional area in a plane perpendicular to the optical axis, where the cross-sectional area of the mode filter defines a non-circular shape, and an aperture having a cross-sectional area in the plane perpendicular to the optical axis, where the cross-sectional area of the aperture defines a non-circular shape.

In some embodiments, the second element may include a mode filter having a cross-sectional area in a plane perpendicular to the optical axis, where the cross-sectional area of the mode filter defines a non-circular shape, and an aperture having a cross-sectional area in the plane perpendicular to the optical axis, where the cross-sectional area of the aperture defines a non-circular shape.

The features, functions, and advantages that have been discussed may be achieved independently in various embodiments of the present disclosure or may be combined with yet other embodiments, further details of which may be seen with reference to the following description and drawings.

### BRIEF DESCRIPTION OF THE DRAWINGS

Having thus described embodiments of the disclosure in general terms, reference will now be made to the accompanying drawings, wherein:

FIG. 1 illustrates a cross-sectional view of a layer structure of a conventional laser;

FIG. 2 illustrates a cross-sectional view of a layer structure of a laser, in accordance with an embodiment of the disclosure;

FIGS. 3A-3H illustrate cross-sectional views of a layer structure of a laser during exemplary steps of a method for manufacturing the laser, in accordance with an embodiment of the disclosure;

FIG. 4A illustrates a cross-sectional view of a layer structure of a laser, in accordance with an embodiment of the disclosure;

FIGS. 4B-4I illustrate exemplary designs for the laser of FIG. 4A, in accordance with embodiments of the disclosure;

FIG. 5 illustrates a one-dimensional array of lasers, in accordance with an embodiment of the disclosure;

FIG. 6 illustrates a two-dimensional array of lasers, in accordance with an embodiment of the disclosure; and

FIG. 7 illustrates a method for manufacturing a vertical-cavity surface-emitting laser (VCSEL), in accordance with an embodiment of the disclosure.

### DETAILED DESCRIPTION OF EMBODIMENTS

Embodiments of the present disclosure will now be described more fully hereinafter with reference to the accompanying drawings, in which some, but not all, embodiments of the disclosure are shown. Indeed, the disclosure may be embodied in many different forms and should not be construed as limited to the embodiments set forth herein; rather, these embodiments are provided so that this disclosure will satisfy applicable legal requirements. Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, a combination of related and unrelated items, etc.), and may be used interchangeably with “one or more.” Where only one item is intended, the phrase “only one” or similar language is used. Also, as used herein, the terms “has,” “have,” “having,” or the like are intended to be open-ended terms. Furthermore, when it is said herein that something is “based on” something else, it may be based on one or more other things as well. In other words, unless expressly indicated otherwise, as used herein “based on” means “based at least in part on” or “based at least partially on.” Also, as used herein, the term “or” is intended to be inclusive when used in a series and may be used interchangeably with “and/or,” unless explicitly stated otherwise (e.g., if used in combination with “either” or “only one of”). As used herein, terms such as “top,” “about,” “around,” and/or the like are used for explanatory purposes in the examples provided below to describe the relative position of components or portions of components. As used herein, the terms “substantially” and “approximately” refer to tolerances within manufacturing and/or engineering standards. Like numbers refer to like elements throughout. No element, act, or instruction used herein should be construed as critical or essential unless explicitly described as such.

As noted, demand for high-speed and high-volume data communication, interconnections and accelerated computation are increasing, and communications, Cloud and Data Center and AI factory providers are increasingly adopting optics-based communication and computation solutions. To meet these demands, high-speed transmitters are being developed. Such high-speed transmitters may include different types of lasers, such as light emitting diodes, top-emitting lasers, bottom-emitting lasers, edge-emitting lasers, GaAs-based lasers, InP-based lasers, directly modulated lasers, distributed-feedback lasers, and/or the like. For example, a vertical-cavity surface-emitting laser (VCSEL) may include a combined mode filter and polarization filter (e.g., a grating) to suppress higher order transverse modes and orthogonal polarization modes of light emitted by the VCSEL. Conventional laser designs include such a combined mode filter and polarization filter on an emission surface through which the light passes. However, using such a combined mode filter and polarization filter requires a tradeoff between suppression of higher order transverse modes and orthogonal polarization modes because a smaller filter diameter improves side-mode suppression but a stronger polarization filter requires a larger diameter filter.

Some embodiments of the present disclosure are directed to a design feature for a laser that provides side-mode suppression that is separate from a design feature providing polarization-mode suppression, such that each design feature may be independently optimized to simultaneously provide a high side-mode suppression ratio and a high polarization-mode suppression ratio with high fabrication yield. For example, a laser (e.g., a VCSEL) according to embodiments of the disclosure may include an active region configured to emit light, an aperture defining an optical axis, a first element positioned along the optical axis on a first side of the active region, and a second element positioned along the optical axis on a second side of the active region opposite the first side of the active region. The first element may be configured to increase a side-mode suppression ratio of the laser, and the second element may be configured to increase a polarization-mode suppression ratio of the laser. Additionally, the first element and the second element may be configured to be independently configurable to increase the side-mode suppression ratio of the laser and the polarization-mode suppression ratio of the laser, respectively. In some embodiments, such lasers may be used for fiber-optic data and analog transmission. Additionally, or alternatively, such lasers may perform one or more single and polarization mode control techniques.

In some embodiments, the present disclosure is directed to a laser design including a mode filter that is separate from a polarization filter (e.g., a wire grid polarizer, a polarizing beam splitter, a polarization maintaining fiber, a liquid crystal polarizer, a thin film polarizer, a grating, and/or the like), such that the mode filter may be optimized to achieve high side-mode suppression while the polarization filter may be simultaneously but independently optimized to achieve high polarization-mode suppression. To this end, a laser may include an active region configured to emit light, an aperture defining an optical axis, and a mode filter positioned along the optical axis and configured to increase a side-mode suppression ratio of the laser. The aperture (e.g., an oxide aperture, a buried tunnel junction, and/or the like) may be configured for confining electrical current and an optical field of the light, where the aperture is positioned between the active region and the mode filter.

Finally, the laser may include a polarization filter positioned along the optical axis on an opposite side of the active region with respect to the mode filter, where the polarization filter is configured to increase a polarization-mode suppression ratio of the laser. The polarization filter may be formed in a mirror region of the laser. In such embodiments, a width of the polarization filter may be greater than a width of the mode filter (e.g., in a direction perpendicular to the optical axis) and/or a width of the aperture. Additionally, or alternatively, a width of the mode filter may be less than a width of the aperture. In some embodiments, the polarization filter may be an etched grating with a period p that is less than λ/n or higher than λ/n, where the active region includes an active material having a refractive index n and the active region is configured to emit light having a wavelength λ. Additionally, or alternatively, the mode filter and/or the aperture may have a non-circular cross-sectional area in a plane perpendicular to the optical axis to suppress higher order transverse modes and/or orthogonal polarization modes. The polarization mode suppression ratio is further increased by the non-circular shape of the mode filter and/or the aperture.

As will be appreciated by one of ordinary skill in the art in view of the present disclosure, the side-mode suppression ratio of a laser corresponds to a ratio of the power of the laser's fundamental mode divided by the power of the laser's lateral side mode with highest power. In this regard, lasers in accordance with embodiments of the disclosure may be configured to achieve a side-mode suppression ratio of 15 dB or greater and/or the like.

As will be appreciated by one of ordinary skill in the art in view of the present disclosure, the polarization mode suppression ratio (PMSR), also referred to as a polarization suppression ratio, of a laser corresponds to a ratio of the power detected with a polarization selective detector in two orthogonal directions. A maximum value of PMSR may be detected at a certain rotation of the polarization selective detector. In some embodiments, lasers in accordance with embodiments of the disclosure may be configured to achieve a polarization mode suppression ratio of 15 dB or greater and/or the like as well as a desired polarization orientation.

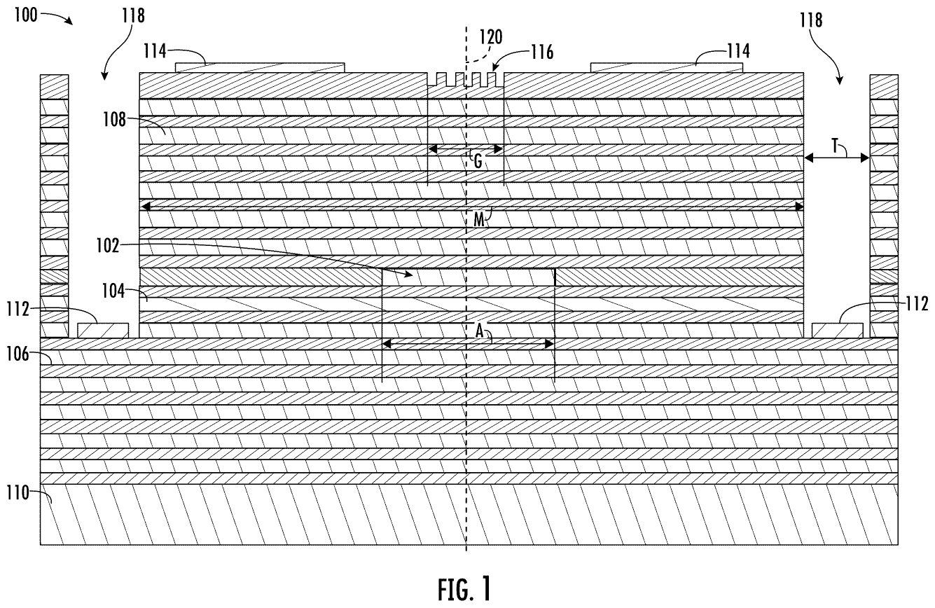

FIG. 1 illustrates a cross-sectional view of a layer structure of a conventional laser 100. In particular, the cross-section of FIG. 1 is taken in a plane that is substantially parallel to an optical axis 120 of the laser 100, where the optical axis 120 is the nominal axis of the light emitted by the laser 100. As shown in FIG. 1, the layer structure may include an aperture 102, an active region 104, a first mirror region 106, a second mirror region 108, a substrate 110, first contacts 112, second contacts 114, a combined mode filter and grating 116, and an etched trench 118. The layer structure of the laser 100 may be formed on the substrate 110.

As shown in FIG. 1, the etched trench 118 may have a width T and may form a mesa having a width M, where the mesa includes the aperture 102, the active region 104, a portion of the first mirror region 106, and the second mirror region 108. As also shown in FIG. 1, the aperture 102 may have a width A, and the combined mode filter and grating 116 may have a width G. Additionally, or alternatively, the aperture 102 may be a buried tunnel junction positioned proximate the active region 104. As will be appreciated by one of ordinary skill in the art in view of the present disclosure, the widths described herein may correspond to diameters of boundaries (e.g., outer peripheries) of elements of the laser 100 when viewed in a plane perpendicular to the optical axis 120 when the respective element has a circular shape.

As shown in FIG. 1, the width G of the combined mode filter and grating 116 is less than the width A of the aperture 102. In this regard, a maximum value of the conventional laser's side-mode suppression ratio may be achieved when the width G is approximately equal to half of the width A. However, such a width G is insufficient to achieve a high polarization-mode suppression ratio, particularly for applications requiring a polarization-mode suppression ratio of greater than 10 decibels. Increasing the width G to values approximately equal to or greater than the width A increases the polarization-mode suppression ratio but also results in a low side-mode suppression ratio. Thus, as noted, such a conventional laser design requires a tradeoff between suppression of side modes and polarization modes.

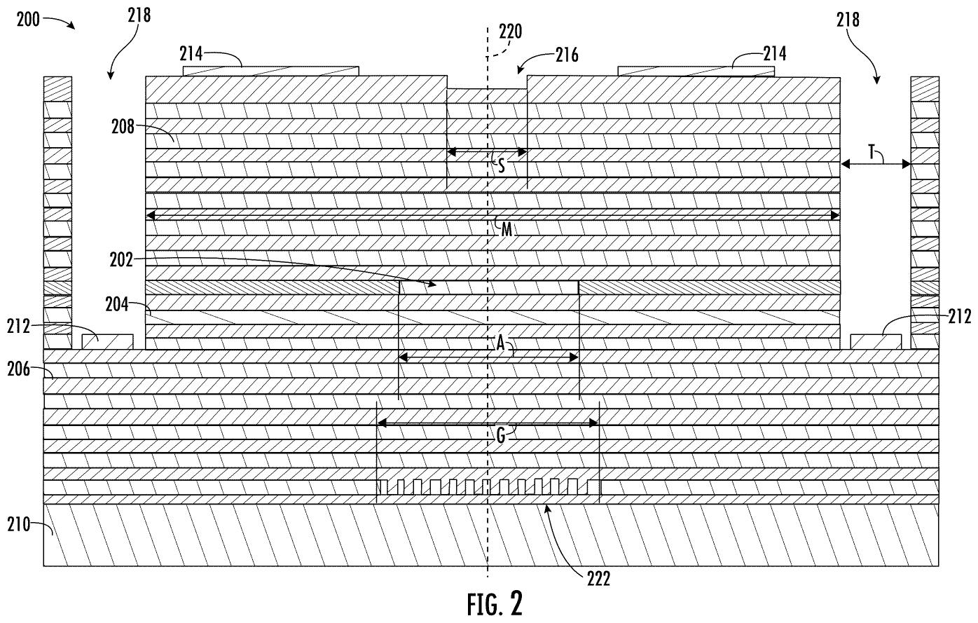

FIG. 2 illustrates a cross-sectional view of a layer structure of a laser 200, in accordance with an embodiment of the disclosure. In particular, the cross-section of FIG. 2 is taken in a plane that is substantially parallel to an optical axis 220 of the laser 200, where the optical axis 220 is the nominal axis of the light emitted by the laser 200. As shown in FIG. 2, the layer structure may include an aperture 202, an active region 204, a first mirror region 206, a second mirror region 208, a substrate 210, first contacts 212, second contacts 214, a mode filter 216, an etched trench 218, and a polarization filter 222 (e.g., a wire grid polarizer, a polarizing beam splitter, a polarization maintaining fiber, a liquid crystal polarizer, a thin film polarizer, a grating, and/or the like). The layer structure of the laser 200 may be wafer-bonded to the substrate 210. In some embodiments, the laser 200 may be configured to emit light having a wavelength between about 400 nanometers and 1,600 nanometers.

As shown in FIG. 2, the active region 204 may be positioned between the first mirror region 206 and the second mirror region 208. The active region 204 may include, for example, one or more quantum wells formed from quantum well layers. In some embodiments, the aperture 202 may be formed in a mirror layer of the second mirror region 208. For example, the aperture 202 may be an oxide aperture formed by oxidizing one or more layers of the second mirror region 208 via the etched trench 218. Additionally, or alternatively, the aperture 202 may be a buried tunnel junction positioned proximate the active region 204.

In some embodiments, the first mirror region 206 (e.g., an n-type mirror region) and the second mirror region 208 (e.g., a p-type mirror region) may include distributed Bragg reflectors formed of multiple alternating semiconductor layers (e.g., of GaAs and AlGaAs), and the first mirror region 206 and the second mirror region 208 may vertically confine light generated in the active region 204. In this regard, the active region 204 may define an active region plane (e.g., a horizontal plane in the orientation of FIG. 2) and emit light parallel to the optical axis 220 of the laser 200, where the optical axis 220 is perpendicular to the active region plane.

As shown in FIG. 2, the first contacts 212 may be positioned in the etched trench 218 on a surface of the first mirror region 206, and the second contacts 214 may be positioned on a surface (e.g., an upper surface) of the second mirror region 208. The first contacts 212 and the second contacts 214 may provide electrical contacts for driving the laser 200.

As shown in FIG. 2, the mode filter 216 may be formed on a surface (e.g., an upper surface) of the second mirror region 208. The mode filter 216 may be configured to suppress side-modes of the light emitted by the laser 200. For example, the mode filter 216 may be configured to make the laser 200 suitable for single-mode transmission.

As shown in FIG. 2, the polarization filter 222 may be formed on a surface of the first mirror region 206 adjacent the substrate 210 and opposite the surface of the first mirror region 206 that is adjacent the active region 204. In some embodiments, the active region 204 may include an active material having a refractive index n and may be configured to emit light having a wavelength λ. In such embodiments, the polarization filter 222 may be an etched grating with a period p that is less than λ/n or higher than λ/n.

As shown in FIG. 2, the etched trench 218 may have a width T and may form a mesa having a width M, where the mesa includes the aperture 202, the active region 204, a portion of the first mirror region 206, and the second mirror region 208. As also shown in FIG. 2, the aperture 202 may have a width A, the mode filter 216 may have a width S, and the polarization filter 222 may have a width G. As will be appreciated by one of ordinary skill in the art in view of the present disclosure, the widths described herein may correspond to diameters of boundaries (e.g., outer peripheries) of elements of the laser 200 when viewed in a plane perpendicular to the optical axis 220 when the respective element has a circular shape.

As shown in FIG. 2, the width S may be less than the width A, and the width G may be greater than the width A. The positioning of the mode filter S on one side of the active region enables achievement of an optical configuration with a highest side-mode suppression ratio. In this regard, a maximum value of the laser's side-mode suppression ratio may be achieved when the width S is approximately equal to half of the width A, and the strength and/or the width G of the polarization filter 222 may be independently configured to achieve a high polarization-mode suppression ratio (e.g., greater than 10 decibels). Thus, the mode filter 216 may be optimized to achieve high side-mode suppression while the polarization filter 222 may be simultaneously but independently optimized to achieve high polarization-mode suppression. The positioning of the polarization filter 222 on the other side of the active region and increasing its width G enables maximum overlapping with the laser mode, which increases the polarization stability. Additionally, or alternatively, an orientation of the polarization filter 222 may be selected based on a direction of highest gain in the active material of the active region 204 to increase the side-mode suppression ratio. For example, the polarization filter 222 may be oriented along the direction of highest gain in the active material.

As will be appreciated by one of ordinary skill in the art in view of the present disclosure, the laser 200 may include other elements, such as metal contacts, one or more other trenches, one or more coatings (e.g., an anti-reflective coating and/or the like), one or more insulators, one or more lenses, and/or the like. Although the laser 200 depicted in FIG. 2 is a top-emitting VCSEL, other embodiments in accordance with the present disclosure may include bottom-emitting VCSELs and/or other types of VCSELs.

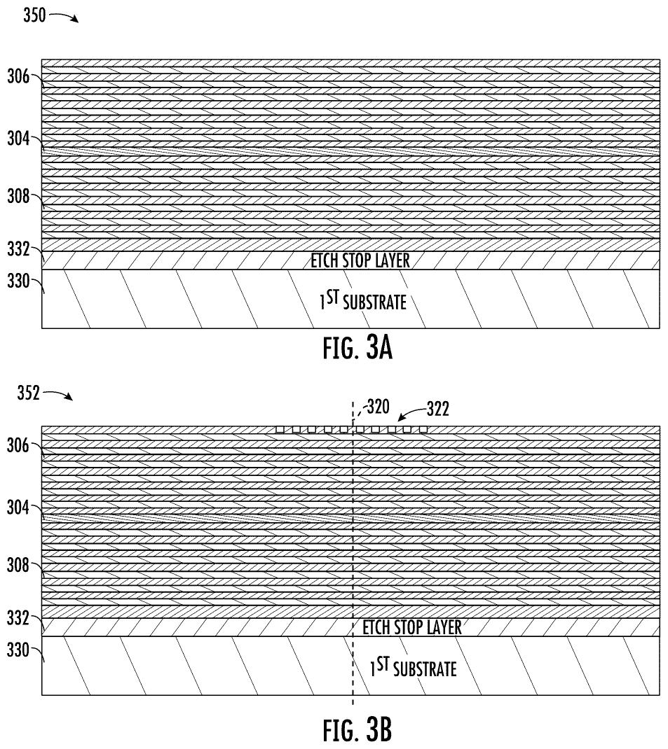

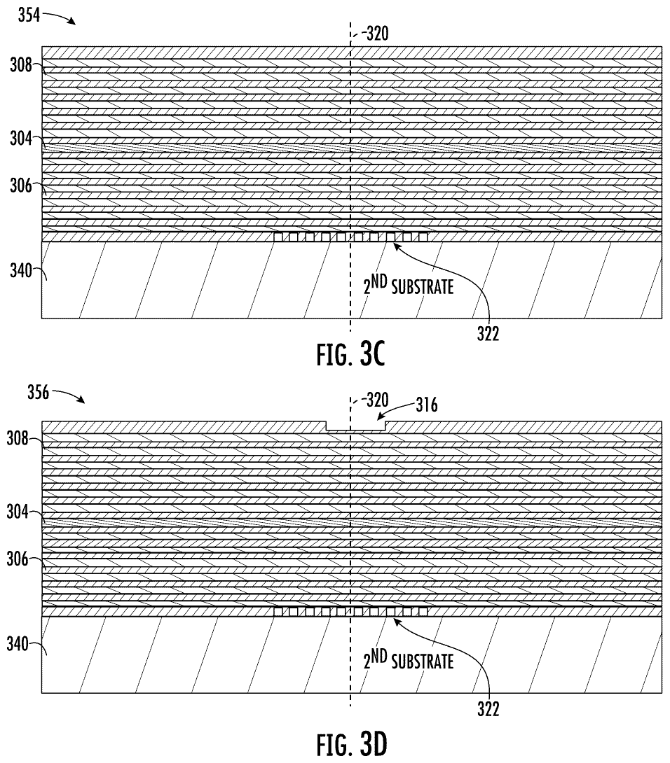

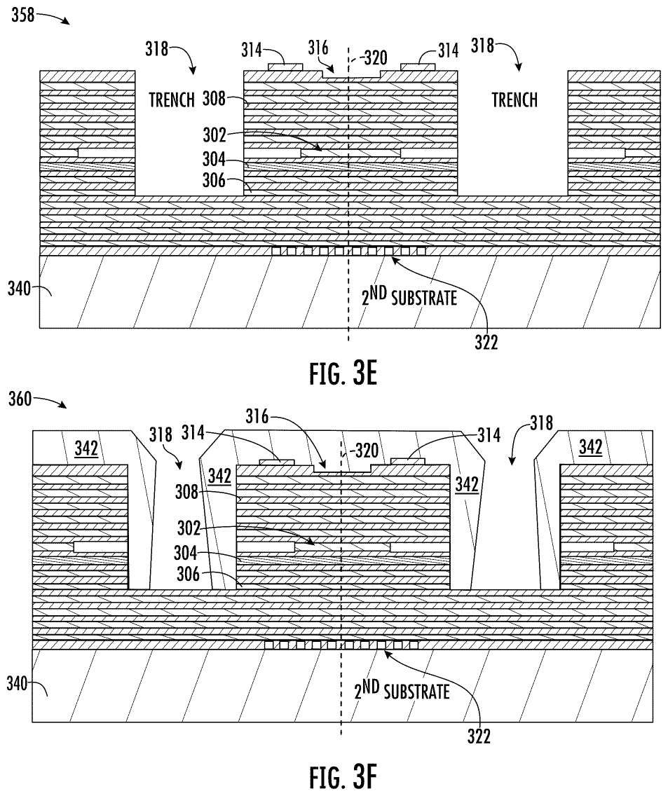

FIGS. 3A-3H illustrate cross-sectional views of a layer structure of a laser during exemplary steps of a method for manufacturing the laser, in accordance with an embodiment of the disclosure. In some embodiments, the laser may have a layer structure similar to the layer structure of the laser 200 as shown and described herein with respect to FIG. 2. Additionally, or alternatively, the method may include an initial step of providing an initial substrate 330 and an etch stop layer 332.

As shown in FIG. 3A, the method may include a step 350 of forming (e.g., growing, depositing, and/or the like) a plurality of epitaxial layers on the etch stop layer 332 positioned on the initial substrate 330. In some embodiments, the method may include forming the etch stop layer 332 on a surface of the initial substrate 330. In some embodiments, and as shown in FIG. 3A, the method may include (i) forming a plurality of epitaxial layers on the etch stop layer 332 to form a second mirror region 308 (e.g., a p-type mirror region similar to the second mirror region 208 as shown and described herein with respect to FIG. 2), (ii) forming another plurality of epitaxial layers on the second mirror region 308 to form an active region 304 (e.g., similar to the active region 204 as shown and described herein with respect to FIG. 2), and (iii) forming another plurality of epitaxial layers on the active region 304 to form a first mirror region 306 (e.g., an n-type mirror region similar to the first mirror region 206 as shown and described herein with respect to FIG. 2).

In this regard, the method may include forming the plurality of epitaxial layers in an order that is reversed as compared to an order in which such epitaxial layers would conventionally be formed. In other words, in a conventional method, the epitaxial layers forming a first mirror region (e.g., an n-type mirror region) would be deposited on a substrate, followed by the epitaxial layers forming the active region, and finally the epitaxial layers forming a second mirror region (e.g., a p-type mirror region). Furthermore, a conventional method would include depositing such layers directly on the substrate, not an etch stop layer. In contrast, methods in accordance with some embodiments of the disclosure include initially forming the second mirror region 308 (e.g., a p-type mirror region), then forming the active region 304, and finally forming the first mirror region 306 (e.g., an n-type mirror region). As will be described herein with respect to FIG. 3C, the epitaxial layers may be formed in this order to allow the epitaxial layers to be removed from the initial substrate 330, rotated 180 degrees, and bonded onto a second substrate 340.

As shown in FIG. 3B, the method may include a step 352 of forming a polarization filter 322 (e.g., a wire grid polarizer, a polarizing beam splitter, a polarization maintaining fiber, a liquid crystal polarizer, a thin film polarizer, a grating, and/or the like) on a surface of the first mirror region 306. In some embodiments, the method may include etching a grating to form the polarization filter 322 in one or more layers of the first mirror region 306, where the grating has a period p. In such embodiments, the method may include selecting the period p such that the period p that is less than λ/n or higher than λ/n, where the active region 304 includes an active material having a refractive index n and is configured to emit light having a wavelength λ. Additionally, or alternatively, the method may include forming the polarization filter 322 such that the polarization filter 322 is aligned with the optical axis 320. By aligning the polarization filter 322 with the optical axis 320, the method may ensure that the polarization filter 322 increases the polarization-mode suppression ratio of the laser. In some embodiments, the polarization filter 322 may be similar to the polarization filter 222 as shown and described herein with respect to FIG. 2.

As shown in FIG. 3C, the method may include a step 354 of transferring the epitaxial layers including the first mirror region 306, the active region 304, the second mirror region 308, and the polarization filter 322 to a second substrate 340 via wafer bonding. For example, the method may include using one or more wafer bonding techniques to bond the surface of the first mirror region 306 including the polarization filter 322 to the second substrate 340 and removing the initial substrate 330 and the etch stop layer from the surface of the second mirror region 308. As will be appreciated by one of ordinary skill in the art in view of the present disclosure, FIG. 3C shows the epitaxial layers rotated 180 degrees as compared to the orientation shown in FIG. 3B and bonded to the second substrate 340. In some embodiments, the second substrate 340 may be similar to the substrate 210 as shown and described herein with respect to FIG. 2.

As shown in FIG. 3D, the method may include a step 356 of forming a mode filter 316 on a surface of the second mirror region 308. In some embodiments, the method may include forming the mode filter 316 such that a center of the mode filter 316 is aligned with the optical axis 320. By aligning the mode filter 316 with the optical axis 320, the method may ensure that the mode filter 316 increases the side-mode suppression ratio of the laser. Additionally, or alternatively, the method may include forming the mode filter 316 such that the mode filter 316 is also aligned with the polarization filter 322. In this way, light emitted by the laser experiences both the polarization-mode suppression of the polarization filter 322 and the side-mode suppression of the mode filter 316. In some embodiments, the mode filter 316 may be similar to the mode filter 216 as shown and described herein with respect to FIG. 2.

As shown in FIG. 3E, the method may include a step 358 that includes (i) etching a trench 318 through the epitaxial layers, (ii) oxidizing one or more layers of the second mirror region 308 via the trench 318 to form an aperture 302, and (iii) disposing second contacts 314 on a surface of the second mirror region 308. In some embodiments, and as shown in FIG. 3E, the method may include etching the trench 318 through the second mirror region 308, the active region 304, and a portion of the first mirror region 306. In some embodiments, the trench 318 may be similar to the trench 218 as shown and described herein with respect to FIG. 2.

As also shown in FIG. 3E, the method may include forming the aperture 302 such that a center of the aperture 302 is aligned with a center of the mode filter 316 and/or a center of the polarization filter 322. For example, and as shown in FIG. 3E, the method may include forming the aperture 302 such that the center of the aperture 302 is aligned with the center of the mode filter 316 and/or the center of the polarization filter 322 and/or such that the optical axis 320 is aligned with the center of the mode filter 316 and/or the center of the polarization filter 322. In some embodiments, the aperture 302 may be similar to the aperture 202 as shown and described herein with respect to FIG. 2. Although the aperture 302 is depicted as an oxide aperture in FIGS. 3E-3F, the aperture 302 may be a buried tunnel junction positioned proximate the active region 304, in some embodiments.

As shown in FIG. 3E, the method may include positioning the second contacts 314 on a surface (e.g., an upper surface) of the second mirror region 308. The second contacts 314 may provide electrical contacts for driving the laser. In some embodiments, the second contacts 314 may be similar to the second contacts 214 as shown and described herein with respect to FIG. 2.

As shown in FIG. 3F, the method may include a step 360 of applying a photoresist material layer and/or combination of several layers including photoresist and other electrical insulation material layer(s) (layer 342 in FIG. 3F) to the mode filter 316, the second contacts 314, and portions of the epitaxial layers. For example, and as shown in FIG. 3F, the method may include applying the layer 342 to the mode filter 316 and the upper surface of the second mirror region 308 as well as portions of the second mirror region 308, the active region 304, and the first mirror region 306 exposed by the trench 318. In some embodiments, the layer 342 may protect the mode filter 316, the upper surface of the second mirror region 308, and the portions of the second mirror region 308, the active region 304, and the first mirror region 306 during metallization to form first contacts 312 (shown in FIG. 3G). In this regard, and as shown in FIG. 3F, the layer 342 may be absent from a bottom surface of the trench 318, which corresponds to an upper surface of a portion of the first mirror region 306.

As shown in FIG. 3G, the method may include a step 362 of forming the first contacts 312 and removing the layer 342. For example, the method may include performing a metal deposition process to form the first contacts 312 on the upper surface of a portion of the first mirror region 306. In some embodiments, the layer 342 may be removed and/or stripped from the mode filter 316, the upper surface of the second mirror region 308, and the portions of the second mirror region 308, the active region 304, and the first mirror region 306 via a chemical etching process. In some embodiments, the first contacts 312 may be similar to the first contacts 212 as shown and described herein with respect to FIG. 2.

As shown in FIG. 3H, the method may include a step 364 of forming an insulating layer 326 and forming a first conductive layer 334 and a second conductive layer 328. In some embodiments, the insulating layer 326 may include a material that electrically insulates the first contacts 312 and the second contacts 314, such as benzocyclobutene, polyamide, Silicon Nitride, Silicon Oxide, and/or the like. As shown in FIG. 3H, the first conductive layer 334 may electrically connect the first contacts 312 to a circuit for driving the laser, and the second conductive layer 328 may electrically connect the second contacts 314 to the circuit for driving the laser.

As will be appreciated by one of ordinary skill in the art in view of the present disclosure, the method described herein with respect to FIGS. 3A-3H may include additional embodiments, such as any single embodiment or any combination of embodiments described elsewhere herein. Furthermore, the laser manufactured via the method described herein with respect to FIGS. 3A-3H may include other elements, such as additional electrical contacts, one or more other trenches, one or more coatings (e.g., an anti-reflective coating and/or the like), one or more insulators, one or more lenses, and/or the like. Although the laser depicted in FIGS. 3A-3H is a top-emitting VCSEL, other embodiments in accordance with the present disclosure may include bottom-emitting VCSELs and/or other types of VCSELs. Furthermore, some embodiments in accordance with the present disclosure may include performing one or more of the steps of the method described herein with respect to FIGS. 3A-3H to manufacture an array of lasers, such as an array of VCSELs.

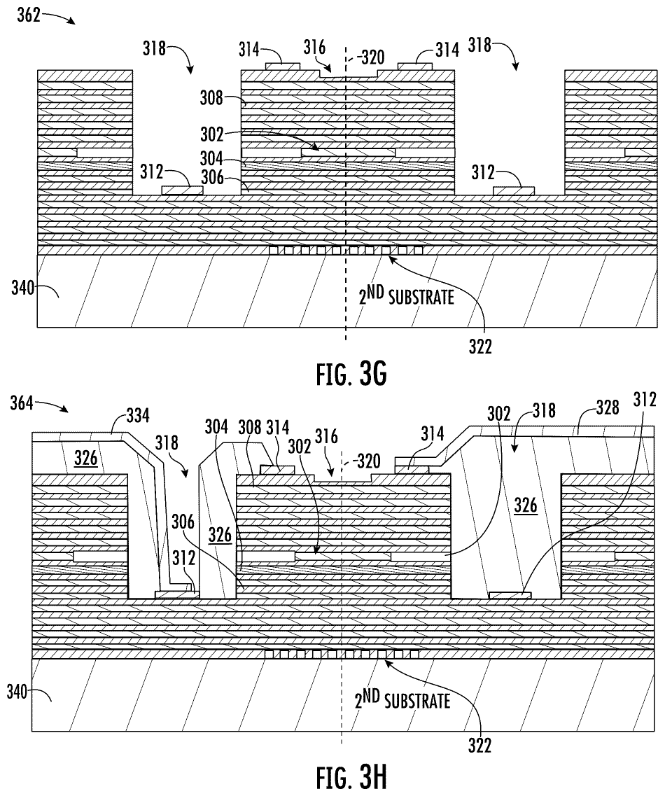

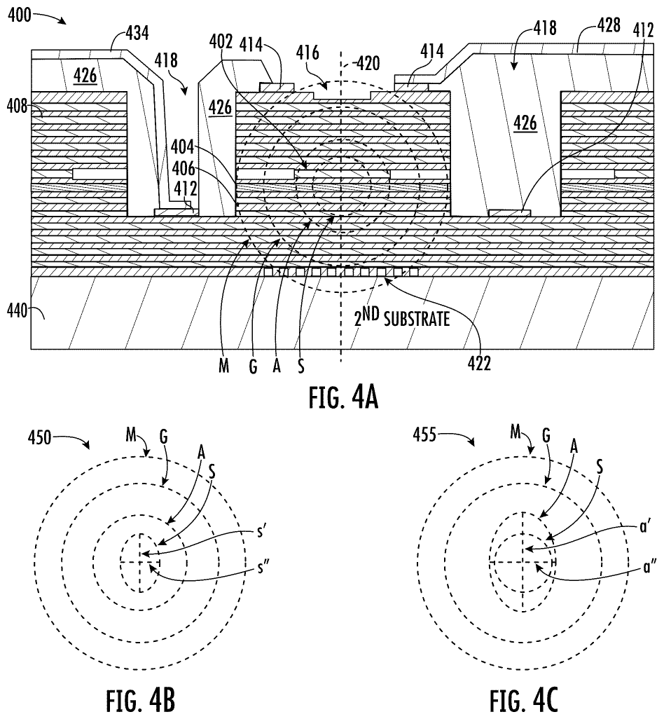

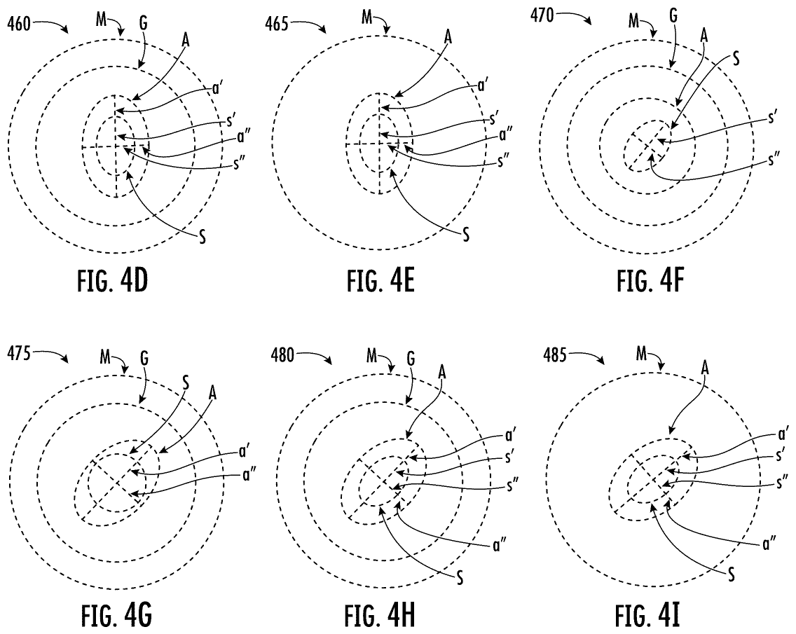

FIG. 4A illustrates a cross-sectional view of a layer structure of a laser 400, in accordance with an embodiment of the disclosure. In particular, the cross-section of FIG. 4A is taken in a plane that is substantially parallel to an optical axis 420 of the laser 400, where the optical axis 420 is the nominal axis of the light emitted by the laser 400. As shown in FIG. 4A, the layer structure may include an aperture 402, an active region 404, a first mirror region 406, a second mirror region 408, a substrate 440, first contacts 412, second contacts 414, a mode filter 416, an etched trench 418, a polarization filter 422 (e.g., a wire grid polarizer, a polarizing beam splitter, a polarization maintaining fiber, a liquid crystal polarizer, a thin film polarizer, a grating, and/or the like), an insulating layer 426, a first electrical contact 434, and a second electrical contact 428. The layer structure of the laser 400 may be wafer-bonded to the substrate 440 (e.g., in a manner similar to that described herein with respect to FIGS. 3A-3H).

In some embodiments, the aperture 402, the active region 404, the first mirror region 406, the second mirror region 408, the substrate 440, the first contacts 412, the second contacts 414, the mode filter 416, the etched trench 418, and the polarization filter 422 may be similar to the aperture 202, the active region 204, the first mirror region 206, the second mirror region 208, the substrate 210, the first contacts 212, the second contacts 214, the mode filter 216, the etched trench 218, and the polarization filter 222, respectively, as shown and described herein with respect to FIG. 2.

Additionally, or alternatively, the aperture 402, the active region 404, the first mirror region 406, the second mirror region 408, the substrate 440, the first contacts 412, the second contacts 414, the mode filter 416, the etched trench 418, the polarization filter 422, the insulating layer 426, the first electrical contact 434, and the second electrical contact 428 may be similar to the aperture 302, the active region 304, the first mirror region 306, the second mirror region 308, the substrate 310, the first contacts 312, the second contacts 314, the mode filter 316, the etched trench 318, the polarization filter 322, the insulating layer 326, the first conductive layer 334, and the second conductive layer 328, respectively, as shown and described herein with respect to FIGS. 3A-3H. Furthermore, the laser 400 may be manufactured by performing one or more of the steps of the method described herein with respect to FIGS. 3A-3H.

As shown in FIG. 4A, the mode filter 416 may have a filter boundary S, the aperture 402 may have an aperture boundary A, the polarization filter 422 may have a polarization filter boundary G, and the mesa formed by the etched trench 418 may have a mesa boundary M. As will be appreciated by one of ordinary skill in the art in view of the present disclosure and as depicted in FIG. 4A, the boundaries described herein may have widths corresponding to diameters when viewed in a plane perpendicular to the optical axis 420 when the respective element has a circular shape. In this regard, the dashed circles shown in FIG. 4A depict the outer peripheries of the corresponding elements of the laser 400 super-imposed on the cross-sectional view of the layer structure of the laser 400.

As shown by the dashed circles in FIG. 4A, the mode filter 416, the aperture 402, the polarization filter 422, and the mesa may have circular-shaped cross-sectional areas in a plane perpendicular to the optical axis 420. As also shown in FIG. 4A, a filter width of the filter boundary S may be less than an aperture width of the aperture boundary A and may be selected to achieve a target side-mode suppression ratio. A polarization filter width of the polarization filter boundary G may be greater than the aperture width of the aperture boundary A, as shown in FIG. 4A, and may be selected to achieve a target polarization-mode suppression ratio. In a laser design such as that depicted in FIG. 4A, the polarization filter 422 may be the primary design element impacting the polarization-mode suppression ratio. In this regard, the rotational orientation of the polarization filter 422 in the plane perpendicular to the optical axis 420 may be selected to achieve a target polarization plane.

FIGS. 4B-4I illustrate exemplary designs for the laser 400 of FIG. 4A, in accordance with embodiments of the disclosure. As will be appreciated by one of ordinary skill in the art in view of the present disclosure, the dashed circles shown in FIGS. 4B-4I depict the outer peripheries of the corresponding elements of the laser 400 when viewed from above in FIG. 4A. Thus, in FIGS. 4B-4I, the filter boundary S may correspond to the mode filter 416 of FIG. 4A, the aperture boundary A may correspond to the aperture 402 of FIG. 4A, the polarization filter boundary G may correspond to the polarization filter 422 of FIG. 4A, and the mesa boundary M may correspond to the mesa formed by the etched trench 418 of FIG. 4A.

As shown in FIG. 4B, the laser design 450 may include a mesa having a mesa boundary M, a polarization filter having a polarization filter boundary G, and an aperture having an aperture boundary A that each have circular-shaped cross-sectional areas in a plane perpendicular to the optical axis 420. As also shown in FIG. 4B, the laser design 450 may include a mode filter having a non-circular filter boundary S that has an elliptically shaped cross-sectional area in the plane perpendicular to the optical axis 420. The elliptical shape of the mode filter may have a major axis s′ and a minor axis s″. In the laser design 450, the non-circular boundary of the mode filter may increase the polarization-mode suppression ratio of the laser.

As shown in FIG. 4C, the laser design 455 may include a mesa having a mesa boundary M, a polarization filter having a polarization filter boundary G, and a mode filter having a filter boundary S that each have circular-shaped cross-sectional areas in a plane perpendicular to the optical axis 420. As also shown in FIG. 4C, the laser design 455 may include an aperture having a non-circular aperture boundary A that has an elliptically shaped cross-sectional area in the plane perpendicular to the optical axis 420. The elliptical shape of the aperture may have a major axis a′ and a minor axis a″. In the laser design 455, the non-circular boundary of the aperture may increase the polarization-mode suppression ratio of the laser.

As shown in FIG. 4D, the laser design 460 may include a mesa having a mesa boundary M and a polarization filter having a polarization filter boundary G that each have circular-shaped cross-sectional areas in a plane perpendicular to the optical axis 420. As also shown in FIG. 4D, the laser design 460 may include a mode filter having a non-circular filter boundary S and an aperture having a non-circular aperture boundary A that each have an elliptically shaped cross-sectional area in the plane perpendicular to the optical axis 420. The elliptical shape of the mode filter may have a major axis s′ and a minor axis s″, and the elliptical shape of the aperture may have a major axis a′ and a minor axis a″. In the laser design 460, the non-circular boundaries of the mode filter and the aperture may increase the polarization-mode suppression ratio of the laser.

As shown in FIG. 4E, the laser design 465 may include a mesa having a mesa boundary M that has a circular-shaped cross-sectional area in a plane perpendicular to the optical axis 420. As also shown in FIG. 4E, the laser design 465 may include a mode filter having a non-circular filter boundary S and an aperture having a non-circular aperture boundary A that each have an elliptically shaped cross-sectional area in the plane perpendicular to the optical axis 420. The elliptical shape of the mode filter may have a major axis s′ and a minor axis s″, and the elliptical shape of the aperture may have a major axis a′ and a minor axis a″. The laser design 465 may not include a polarization filter. In this regard, the non-circular boundaries of the mode filter and the aperture may increase the polarization-mode suppression ratio of the laser in the laser design 460 such that the polarization filter is not required.

As shown in FIG. 4F, the laser design 470 may be similar to the laser design 450 as shown and described herein with respect to FIG. 4B. However, as shown in FIG. 4F, the laser design 470 may include a mode filter having a non-circular, elliptical filter boundary S where the rotational orientation of the major axis s′ in the plane perpendicular to the optical axis 420 may be selected to achieve a target polarization plane. Additionally, or alternatively, the laser design 470 may also include a polarization filter having a polarization filter boundary G and a rotational orientation in the plane perpendicular to the optical axis 420 selected to achieve the target polarization plane in conjunction with the rotational orientation of the mode filter.

As shown in FIG. 4G, the laser design 475 may be similar to the laser design 455 as shown and described herein with respect to FIG. 4C. However, as shown in FIG. 4G, the laser design 475 may include an aperture having a non-circular, elliptical aperture boundary A where the rotational orientation of the major axis a′ in the plane perpendicular to the optical axis 420 may be selected to achieve a target polarization plane. Additionally, or alternatively, the laser design 475 may also include a polarization filter having a polarization filter boundary G and a rotational orientation in the plane perpendicular to the optical axis 420 selected to achieve the target polarization plane in conjunction with the rotational orientation of the aperture.

As shown in FIG. 4H, the laser design 480 may be similar to the laser design 460 as shown and described herein with respect to FIG. 4D. However, as shown in FIG. 4H, the laser design 480 may include a mode filter having a non-circular, elliptical filter boundary S where the rotational orientation of the major axis s′ in the plane perpendicular to the optical axis 420 may be selected to achieve a target polarization plane. The laser design 480 may also include an aperture having a non-circular, elliptical aperture boundary A where the rotational orientation of the major axis a′ in the plane perpendicular to the optical axis 420 may be selected to achieve the target polarization plane in conjunction with the rotational orientation of the mode filter. Additionally, or alternatively, the laser design 475 may also include a polarization filter having a polarization filter boundary G and a rotational orientation in the plane perpendicular to the optical axis 420 selected to achieve the target polarization plane in conjunction with the rotational orientation of the aperture and the rotational orientation of the mode filter.

As shown in FIG. 4I, the laser design 485 may be similar to the laser design 465 as shown and described herein with respect to FIG. 4E. However, as shown in FIG. 4I, the laser design 485 may include a mode filter having a non-circular, elliptical filter boundary S where the rotational orientation of the major axis s′ in the plane perpendicular to the optical axis 420 may be selected to achieve a target polarization plane. The laser design 480 may also include an aperture having a non-circular, elliptical aperture boundary A where the rotational orientation of the major axis a′ in the plane perpendicular to the optical axis 420 may be selected to achieve the target polarization plane in conjunction with the rotational orientation of the mode filter. The laser design 485 may not include a polarization filter. In this regard, the non-circular boundaries of the mode filter and the aperture may increase the polarization-mode suppression ratio of the laser in the laser design 485 such that the polarization filter is not required. Furthermore, the rotational orientations of the mode filter and the aperture may be sufficient to achieve the target polarization plane such that the polarization filter is not required.

As will be appreciated by one of ordinary skill in the art in view of the present disclosure, the substrate on which the mesa of a laser is formed (e.g., the first substrate 330 of FIGS. 3A and 3B) may have a crystal orientation characterized by a crystallographic axis that may be governed by atomic ordering of the material of the substrate (e.g., a spatial anisotropy). In some embodiments, the crystal orientation and/or the crystallographic axis of the substrate may govern an inherent polarization plane of the laser. In this regard, for laser designs including one or more elements with non-circular boundaries (e.g., such as lasers designs 450-485), the shape and/or orientation of the one or more elements may be selected to align with the crystallographic axis of the substrate and achieve a target polarization plane, an increased polarization-mode suppression ratio, a maximum polarization-mode suppression ratio, a target side-mode suppression ratio, and/or the like. For example, a shape and orientation of an aperture may be selected to align with the crystallographic axis of the substrate and achieve a maximum polarization-mode suppression ratio and a target side-mode suppression ratio.

In some embodiments, the crystallographic axis of the substrate may define an inherent polarization direction. In such embodiments, the orientation of one or more elements with non-circular boundaries (e.g., an aperture, a mode filter, and/or the like) may be selected such that a major axis, longest dimension, and/or the like of the one or more elements (e.g., a major axis s′, a major axis a′, and/or the like) is parallel to the crystallographic axis and/or the inherent polarization direction.

As will be appreciated by one of ordinary skill in the art in view of the present disclosure, the laser 400 of FIG. 4A and the laser designs 450-485 of FIGS. 4B-4I demonstrate multiple techniques for rotation of the polarization plane to achieve a target polarization plane. With respect to the laser 400, the polarization plane may be rotated by rotating the polarization filter 422 to achieve a target polarization plane. With respect to laser design 450 of FIG. 4B and the laser design 470 of FIG. 4F, the polarization plane may be rotated by rotating the polarization filter and/or rotating the mode filter, due to the non-circular, elliptical filter boundary S, to achieve a target polarization plane. For example, the polarization plane of the laser design 450 may be different from the polarization plane of the laser design 470 due to the difference in orientation of the major axis s′ of the non-circular, elliptical filter boundary S.

With respect to laser design 455 of FIG. 4C and the laser design 475 of FIG. 4G, the polarization plane may be rotated by rotating the polarization filter and/or rotating the aperture, due to the non-circular, elliptical aperture boundary A, to achieve a target polarization plane. For example, the polarization plane of the laser design 455 may be different from the polarization plane of the laser design 475 due to the difference in orientation of the major axis a′ of the non-circular, elliptical aperture boundary A.

With respect to the laser design 460 of FIG. 4D and the laser design 480 of FIG. 4H, the polarization plane may be rotated by rotating the polarization filter, rotating the aperture due to the non-circular, elliptical aperture boundary A, and/or rotating the mode filter due to the non-circular, elliptical filter boundary S, to achieve a target polarization plane. For example, the polarization plane of the laser design 460 may be different from the polarization plane of the laser design 480 due to the difference in orientation of the major axis a′ of the non-circular, elliptical aperture boundary A and the major axis s′ of the non-circular, elliptical filter boundary S.

With respect to the laser design 465 of FIG. 4E and the laser design 485 of FIG. 4I, the polarization plane may be rotated by rotating the aperture due to the non-circular, elliptical aperture boundary A and/or rotating the mode filter due to the non-circular, elliptical filter boundary S to achieve a target polarization plane. For example, the polarization plane of the laser design 465 may be different from the polarization plane of the laser design 485 due to the difference in orientation of the major axis a′ of the non-circular, elliptical aperture boundary A and the major axis s′ of the non-circular, elliptical filter boundary S.

Although non-circular boundaries of elements (e.g., mode filters, apertures, and/or the like) of laser designs described herein refer to elements having elliptically-shaped boundaries, laser designs in accordance with embodiments of the disclosure may have non-circular boundaries of other shapes and even asymmetrical shapes. For example, a laser design may include an element having a boundary in a plane perpendicular to an optical axis that corresponds to an ellipse with a compressed border along a minor axis (e.g., a bean-type shape, an ellipse with a concavity on one side along a minor axis, and/or the like) such that the boundary of the element has only one axis of symmetry. As another example, a laser design may include an element having a boundary in a plane perpendicular to an optical axis that corresponds to an ellipse with a compressed and/or concave border in multiple locations such that the boundary of the element is asymmetrical.

As will be appreciated by one of ordinary skill in the art in view of the present disclosure, multiple elements (e.g., mode filters, apertures, polarization filters, and/or the like) may be configured to increase the polarization-mode suppression ratio. For example, a shape and/or an orientation of an aperture may be configured to increase the polarization-mode suppression ratio (e.g., using one or more of the techniques described herein), and a size and/or an orientation of a polarization filter may also be configured to increase the polarization-mode suppression ratio (e.g., using one or more of the techniques described herein).

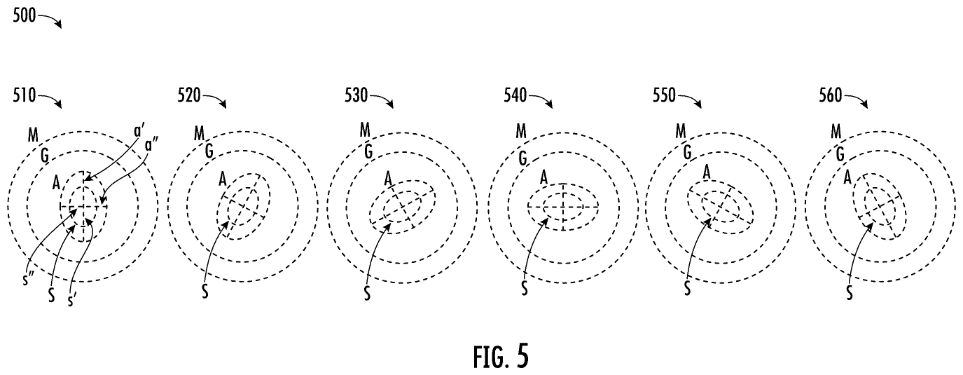

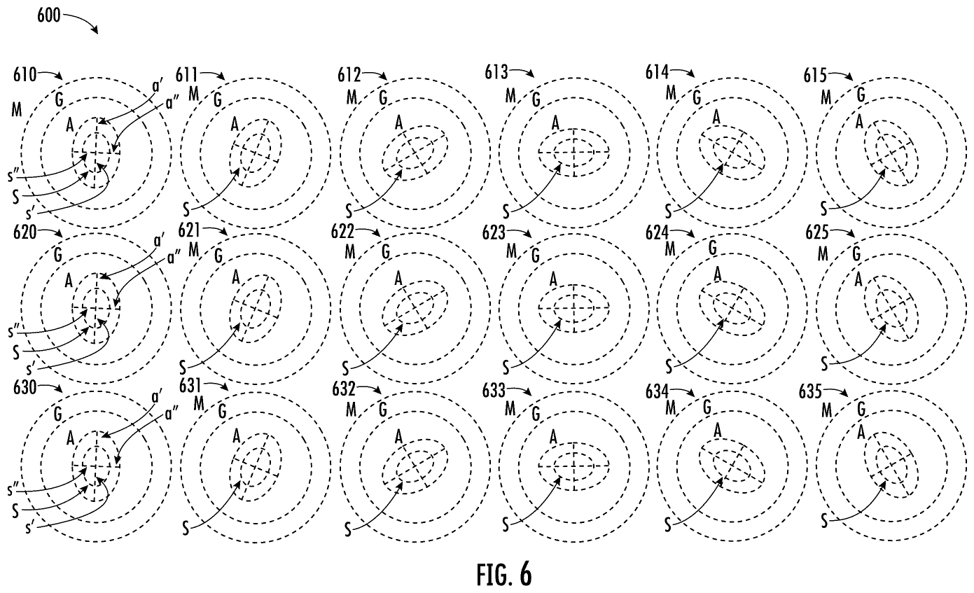

FIG. 5 illustrates a one-dimensional array 500 of lasers, in accordance with an embodiment of the disclosure. In this regard, FIG. 5 illustrates exemplary laser designs 510-560 for lasers having the same structure as the laser 400 of FIG. 4A, in accordance with embodiments of the disclosure. As will be appreciated by one of ordinary skill in the art in view of the present disclosure, the dashed circles shown in FIG. 5 depict the outer peripheries of the corresponding elements of the laser 400. Thus, in FIG. 5, the filter boundaries S may correspond to mode filters similar to the mode filter 416 of FIG. 4A, the aperture boundaries A may correspond to apertures similar to the aperture 402 of FIG. 4A, the polarization filter boundaries G may correspond to polarization filters similar to the polarization filter 422 of FIG. 4A, and the mesa boundaries M may correspond to mesas similar to the mesa formed by the etched trench 418 of FIG. 4A.

As shown in FIG. 5, the array 500 includes laser designs 510-560 similar to the laser design 460 as shown and described herein with respect to FIG. 4D. In particular, each of the laser designs 510-560 may include a mesa having a mesa boundary M and a polarization filter having a polarization filter boundary G that each have circular-shaped cross-sectional areas in a plane perpendicular to the optical axis 420. Each of the laser designs 510-560 may also include a mode filter having a non-circular filter boundary S and an aperture having a non-circular filter aperture boundary A that each have an elliptically shaped cross-sectional area in the plane perpendicular to an optical axis. Although only labeled with respect to the laser design 510, for each of the laser designs 510-560, the elliptical shape of the mode filter may have a major axis s′ and a minor axis s″, and the elliptical shape of the aperture may have a major axis a′ and a minor axis a″.

As shown in FIG. 5, the major axes a′ and s′ for the laser designs 510-560 are oriented at different angles as compared to each other. In particular, starting with the laser design 520, the major axes a′ and s′ for each laser design are rotated clockwise around the optical axis by 30 degrees as compared to the major axes a′ and s′ for the laser design to the left of a given laser design in the array. For example, the major axes a′ and s′ for the laser design 520 are rotated clockwise around the optical axis by 30 degrees as compared to the major axes a′ and s′ for the laser design 510. As another example, the major axes a′ and s′ for the laser design 530 are rotated clockwise around the optical axis by 30 degrees as compared to the major axes a′ and s′ for the laser design 520. Thus, the major axes a′ and s′ for the laser design 560 are rotated clockwise around the optical axis by 150 degrees as compared to the major axes a′ and s′ for the laser design 510.

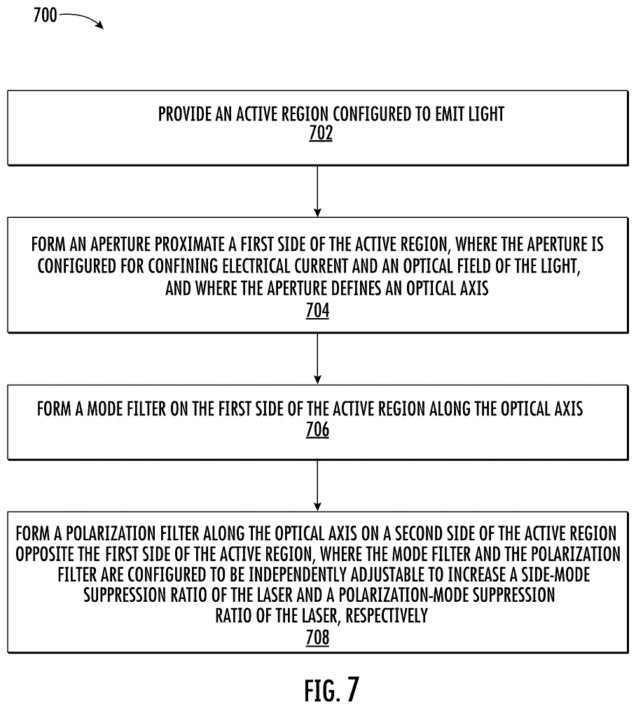

The technique of the present disclosure enables reaching linear polarization control of VCSEL(s) and even polarization multiplexing of VCSEL arrays. With strong aggregated polarization strength, polarization division multiplexing may be implemented by using an array of VCELs with a predetermined polarization for any angle values as described below. By rotating the orientation of the non-circular aperture boundary A and the non-circular filter boundary S across the array 500, the array 500 may be deployed for polarization division multiplexing applications. For example, each laser design of the array 500 may transmit a distinct signal channel, and the signal channels may be optically transmitted together. Furthermore, although a 30-degree rotation is demonstrated in the array 500 of FIG. 5, other angle values (e.g., 10 degrees, 15 degrees, 20 degrees, 25 degrees, 45 degrees, 60 degrees, and/or the like) may be used for rotation, in some embodiments. Additionally, or alternatively, although the laser design 460 as shown and described herein with respect to FIG. 4D is used in the array 500, one or more of the other laser designs as shown and described herein with respect to FIGS. 4A-4I may be used in a similar array employing rotated orientations to achieve polarization division multiplexing. Therefore, the method of manufacturing, as will be described below with respect to FIG. 7, may include configuring VCSEL arrays with relatively different target polarization orientation (e.g., directions and angles of polarizations) and/or configuring lateral mode intensities of a single VCSEL element in an array by patterning and manufacturing non-circular (e.g., asymmetrically) shaped elements (e.g., an aperture, a mode filter, a polarization filter, and/or the like) with relatively different target polarization orientation (e.g., directions and angles).

FIG. 6 illustrates a two-dimensional array 600 of lasers, in accordance with an embodiment of the disclosure. The array 600 includes laser designs 610-635 similar to the laser design 460 as shown and described herein with respect to FIG. 4D. In particular, each of the laser designs 610-635 may include a mesa having a mesa boundary M and a polarization filter having a polarization filter boundary G that each have circular-shaped cross-sectional areas in a plane perpendicular to the optical axis 420. Each of the laser designs 610-635 may also include a mode filter having a non-circular filter boundary S and an aperture having a non-circular aperture boundary A that each have an elliptically shaped cross-sectional area in the plane perpendicular to an optical axis. Although only labeled with respect to the laser designs 610, 620, and 630, for each of the laser designs 610-635, the elliptical shape of the mode filter may have a major axis s′ and a minor axis s″, and the elliptical shape of the aperture may have a major axis a′ and a minor axis a″.

Similar to FIG. 5, and as shown in FIG. 6, the major axes a′ and s′ for the laser designs on each row of the array 600 are oriented at different angles as compared to each other. In particular, starting with laser designs 611, 621, and 631, the major axes a′ and s′ for each laser design are rotated clockwise around the optical axis by 30 degrees as compared to the major axes a′ and s′ for the laser design to the left of a given laser design in the row of the array 600. For example, the major axes a′ and s′ for the laser design 611 are rotated clockwise around the optical axis by 30 degrees as compared to the major axes a′ and s′ for the laser design 610. As another example, the major axes a′ and s′ for the laser design 612 are rotated clockwise around the optical axis by 30 degrees as compared to the major axes a′ and s′ for the laser design 611. Thus, the major axes a′ and s′ for the laser designs 615, 625, and 635 are rotated clockwise around the optical axis by 150 degrees as compared to the major axes a′ and s′ for the laser designs 610, 620, and 630, respectively.

Again, by rotating the orientation of the non-circular aperture boundary A and the non-circular filter boundary S across the rows of the array 600, the array 600 may be deployed for two-dimensional polarization division multiplexing applications. Furthermore, although a 30-degree rotation is demonstrated in the array 600 of FIG. 6, other angle values (e.g., 10 degrees, 15 degrees, 20 degrees, 25 degrees, 45 degrees, 60 degrees, and/or the like) may be used for rotation, in some embodiments. Additionally, or alternatively, although the laser design 460 as shown and described herein with respect to FIG. 4D is used in the array 600, one or more of the other laser designs as shown and described herein with respect to FIGS. 4A-4I may be used in a similar array employing rotated orientations to achieve polarization division multiplexing. In some embodiments, rather than rotating the orientation of the non-circular aperture boundary A and the non-circular filter boundary S across the rows of the array 600, the orientation of the non-circular aperture boundary A and the non-circular filter boundary S may be rotated across columns of the array 600.

FIG. 7 illustrates a method 700 for manufacturing a VCSEL, in accordance with an embodiment of the disclosure. In some embodiments, one or more steps from the method 700 may be used to manufacture a laser described herein with respect to one or more of FIGS. 2, 3A-3H, and/or 4A-4I. Additionally, or alternatively, one or more steps from the method 700 may be used to manufacture a laser and/or an array of lasers described herein with respect to one or more of FIGS. 5 and 6. In some embodiments, the method 700 may include one or more of the steps described herein with respect to FIGS. 3A-3H.

As shown in block 702, the method 700 may include providing an active region configured to emit light. For example, the active region may be formed via epitaxial growth of compound materials using metal-organic chemical vapor deposition (MOCVD), molecular-beam epitaxy (MBE), and/or the like. In some embodiments, the active region may include, for example, one or more quantum wells formed from quantum well layer materials. For example, the active region may include GaAs, InGaAs, AlGaAs, GaP, GaAsP, InGaP, AlGaAsP, InGaAlAs, InGaAsP compound materials, and/or the like.

As shown in block 704, the method 700 may include forming an aperture proximate a first side of the active region, where the aperture is configured for confining electrical current and an optical field of the light, and where the aperture defines an optical axis. For example, the aperture may be formed via epitaxial growth of compound materials using MOCVD, MBE, and/or the like.

In some embodiments, the method 700 may include selecting a shape and orientation of the aperture to achieve a target polarization-mode suppression ratio and, when forming the aperture, forming the aperture to have the selected shape and the selected orientation. Additionally, or alternatively, the method 700 may include selecting a shape and orientation of the aperture to achieve a target polarization-mode suppression ratio and a target side-mode suppression ratio and, when forming the aperture, forming the aperture to have the selected shape and the selected orientation.

In some embodiments, the method 700 may include forming the aperture via lateral oxidation (e.g., of one or more layers of a mirror region). Additionally, or alternatively, the method 700 may include forming a buried tunnel junction for the aperture. In some embodiments, the aperture may have a cross-sectional area in a plane perpendicular to the optical axis, where the cross-sectional area defines a non-circular shape. Additionally, or alternatively, the non-circular shape may have at most one axis of symmetry.

As shown in block 706, the method 700 may include forming a mode filter on the first side of the active region along the optical axis. In some embodiments, the mode filter may be configured to suppress higher order transverse modes and/or increase a side-mode suppression ratio of the laser. Additionally, or alternatively, the mode filter may have a cross-sectional area in a plane perpendicular to the optical axis, where the cross-sectional area defines a non-circular shape. In some embodiments, the mode filter may have a width in a direction perpendicular to the optical axis is less than a width of the aperture in the direction perpendicular to the optical axis.

As shown in block 708, the method 700 may include forming a polarization filter (e.g., a wire grid polarizer, a polarizing beam splitter, a polarization maintaining fiber, a liquid crystal polarizer, a thin film polarizer, a grating, and/or the like) along the optical axis on a second side of the active region opposite the first side of the active region. In some embodiments, the mode filter and the polarization filter may be configured to be independently configurable (e.g., while designing the laser characteristics before manufacturing) to increase a side-mode suppression ratio of the laser and a polarization-mode suppression ration of the laser, respectively. Additionally, or alternatively, the method 700 may include selecting a shape, orientation, and alignment of the polarization filter to achieve a target polarization-mode suppression ratio and, when forming the polarization filter, forming the polarization filter to have the selected shape, the selected orientation, and the selected alignment.

In some embodiments, the polarization filter may have a width in a direction perpendicular to the optical axis that is greater than a width of the mode filter in the direction perpendicular to the optical axis. Additionally, or alternatively, the polarization filter may have a width in a direction perpendicular to the optical axis that is greater than a width of the aperture in the direction perpendicular to the optical axis. In some embodiments, the polarization filter may be an etched polarization filter with a period p that is less than A/n or higher than A/n, where the active region includes an active material having a refractive index n and the active region is configured to emit light having a wavelength A.

In some embodiments, the method 700 may include forming a layer structure on a first substrate, where the layer structure includes a first mirror region proximate the first substrate, the active region, and a second mirror region. Additionally, or alternatively, the method 700 may include forming the polarization filter on the second mirror region along the optical axis. In some embodiments, the method 700 may include transferring the layer structure to a second substrate such that the polarization filter and the second mirror region are proximate the second substrate and removing the first substrate from the layer structure. Additionally, or alternatively, the method 700 may include, when forming the mode filter, forming the mode filter on the layer structure after removing the first substrate from the layer structure.

In some embodiments, the VCSEL may be one of a plurality of VCSELs in an array, and the method 700 may include selecting, for each VCSEL in the array, a target polarization orientation, where at least two VCSELs in the array have different selected target polarization orientations. Additionally, or alternatively, the method 700 may include forming, for each VCSEL in the array, at least one of an aperture or a polarization filter to achieve the selected target polarization orientation for the given VCSEL. For example, the array may be a one-dimensional array similar to the array 500 as shown and described herein with respect to FIG. 5 and/or a two-dimensional array similar to the array 600 as shown and described herein with respect to FIG. 6.

In some embodiments, the method 700 may include forming a layer structure on a first substrate, where the layer structure includes the active region, and where the first substrate has a crystallographic axis. Additionally, or alternatively, the method 700 may include selecting a shape and an orientation of the aperture to align with the crystallographic axis and to increase a polarization-mode suppression ratio (e.g., to achieve a maximum polarization-mode suppression ratio) and to achieve a target side-mode suppression ratio, where forming the aperture includes forming the aperture to have the selected shape and the selected orientation.

Method 700 may include additional embodiments, such as any single embodiment or any combination of embodiments described herein. Although FIG. 7 shows example blocks of a method 700, in some embodiments, the method 700 may include additional blocks, fewer blocks, different blocks, or differently arranged blocks than those depicted in FIG. 7. Additionally, or alternatively, two or more of the blocks of the method 700 may be performed in parallel.

As will be appreciated by one of ordinary skill in the art in view of this disclosure, the present disclosure may include and/or be embodied as an apparatus (including, for example, a photodetector, a device, and/or the like), as a method (including, for example, a manufacturing method, a computer-implemented process, and/or the like), or as any combination of the foregoing.

Although many embodiments of the present disclosure have just been described above, the present disclosure may be embodied in many different forms and should not be construed as limited to the embodiments set forth herein; rather, these embodiments are provided so that this disclosure will satisfy applicable legal requirements. Also, it will be understood that, where possible, any of the advantages, features, functions, devices, and/or operational aspects of any of the embodiments of the present disclosure described and/or contemplated herein may be included in any of the other embodiments of the present disclosure described and/or contemplated herein, and/or vice versa.

While certain exemplary embodiments have been described and shown in the accompanying drawings, it is to be understood that such embodiments are merely illustrative of and not restrictive on the broad disclosure and that this disclosure is not to be limited to the specific constructions and arrangements shown and described, as various other changes, combinations, omissions, modifications and substitutions, in addition to those set forth in the above paragraphs, are possible. In light of this disclosure, those skilled in the art will appreciate that various adaptations, modifications, and combinations of the just described embodiments may be configured without departing from the scope and spirit of the disclosure. Therefore, it is to be understood that, within the scope of the appended claims, the disclosure may be practiced other than as specifically described herein.

1. A vertical-cavity surface-emitting laser (VCSEL), comprising:
an active region configured to emit light;
an aperture configured for confining electrical current and an optical field of the light, wherein the aperture defines an optical axis;
a mode filter positioned along the optical axis on a first side of the active region, wherein the mode filter is configured to increase a side-mode suppression ratio of the VCSEL; and
a polarization filter positioned along the optical axis on a second side of the active region opposite the first side of the active region, wherein the polarization filter is configured to increase a polarization-mode suppression ratio of the VCSEL; and
wherein the mode filter and the polarization filter are configured to be independently configurable to increase the side-mode suppression ratio of the VCSEL and the polarization-mode suppression ratio of the VCSEL, respectively.

2. The VCSEL of claim 1, wherein the mode filter has a cross-sectional area in a plane perpendicular to the optical axis, wherein the cross-sectional area defines a non-circular shape.

3. The VCSEL of claim 1, comprising a mirror region positioned along the optical axis on the second side of the active region, wherein the polarization filter is formed in the mirror region.

4. The VCSEL of claim 1, wherein a width of the polarization filter in a direction perpendicular to the optical axis is greater than a width of the mode filter in the direction perpendicular to the optical axis.

5. The VCSEL of claim 1, wherein the active region comprises an active material having a refractive index n, wherein the active region is configured to emit light having a wavelength λ, wherein the polarization filter is an etched grating with a period p that is less than λ/n or higher than λ/n.

6. The VCSEL of claim 1, wherein the aperture is configured for confining the electrical current and the optical field of the light via lateral oxidation.

7. The VCSEL of claim 1, wherein the aperture is configured for confining the electrical current and the optical field of the light via a buried tunnel junction.

8. The VCSEL of claim 1, wherein a width of the mode filter in a direction perpendicular to the optical axis is less than a width of the aperture in the direction perpendicular to the optical axis.

9. The VCSEL of claim 1, wherein a width of the polarization filter in a direction perpendicular to the optical axis is greater than a width of the aperture in the direction perpendicular to the optical axis.

10. The VCSEL of claim 1, wherein the aperture has a cross-sectional area in a plane perpendicular to the optical axis, wherein the cross-sectional area defines a non-circular shape.

11. The VCSEL of claim 1, wherein the VCSEL is configured to emit the light having a wavelength between about 400 nanometers and 1,600 nanometers.

12. A method of manufacturing a vertical-cavity surface-emitting laser (VCSEL), the method comprising:
providing an active region configured to emit light;
forming an aperture proximate a first side of the active region, wherein the aperture is configured for confining electrical current and an optical field of the light, and wherein the aperture defines an optical axis;
forming a mode filter on the first side of the active region along the optical axis; and
forming a polarization filter along the optical axis on a second side of the active region opposite the first side of the active region; and
wherein the mode filter and the polarization filter are configured to be independently configurable to increase a side-mode suppression ratio of the VCSEL and a polarization-mode suppression ratio of the VCSEL, respectively.

13. The method of claim 12, comprising forming a layer structure on a first substrate, wherein the layer structure comprises a first mirror region proximate the first substrate, the active region, and a second mirror region.

14. The method of claim 13, comprising forming the polarization filter on the second mirror region along the optical axis.

15. The method of claim 14, comprising:
transferring the layer structure to a second substrate such that the polarization filter and the second mirror region are proximate the second substrate; and
removing the first substrate from the layer structure.

16. The method of claim 15, wherein forming the mode filter comprises forming the mode filter on the layer structure after removing the first substrate from the layer structure.

17. The method of claim 12, comprising selecting a shape and an orientation of the aperture to achieve a target polarization-mode suppression ratio, wherein forming the aperture comprises forming the aperture to have the selected shape and the selected orientation.

18. The method of claim 12, comprising selecting a shape and an orientation of the aperture to achieve a target polarization-mode suppression ratio and a target side-mode suppression ratio, wherein forming the aperture comprises forming the aperture to have the selected shape and the selected orientation.

19. The method of claim 12, comprising selecting a shape, an orientation, and an alignment of the polarization filter to achieve a target polarization-mode suppression ratio, wherein forming the polarization filter comprises forming the polarization filter to have the selected shape, the selected orientation, and the selected alignment.

20. The method of claim 12, wherein the VCSEL is one of a plurality of VCSELs in an array, and wherein the method comprises:
selecting, for each VCSEL in the array, a target polarization orientation, wherein at least two VCSELs in the array have different selected target polarization orientations; and
forming, for each VCSEL in the array, at least one of an aperture or a polarization filter to achieve the selected target polarization orientation for the given VCSEL.

21. The method of claim 12, comprising:
forming a layer structure on a first substrate, wherein the layer structure comprises the active region, and wherein the first substrate has a crystallographic axis; and
selecting a shape and an orientation of the aperture to align with the crystallographic axis and to increase a polarization-mode suppression ratio and to achieve a target side-mode suppression ratio, wherein forming the aperture comprises forming the aperture to have the selected shape and the selected orientation.

22. A laser, comprising:
an active region configured to emit light, wherein the active region defines an optical axis;
a mode filter positioned along the optical axis on a first side of the active region, wherein the mode filter is configured to increase a side-mode suppression ratio of the laser; and
a polarization filter positioned along the optical axis on a second side of the active region opposite the first side of the active region, wherein the polarization filter is configured to increase a polarization-mode suppression ratio of the laser; and
wherein the mode filter and the polarization filter are configured to be independently adjustable to increase the side-mode suppression ratio of the laser and the polarization-mode suppression ratio of the laser, respectively.

23. A laser, comprising:
an active region configured to emit light substantially parallel to an optical axis;
a first element positioned along the optical axis, wherein the first element is configured to increase a side-mode suppression ratio of the laser;
a second element positioned along the optical axis, wherein the second element is configured to increase a polarization-mode suppression ratio of the laser; and
wherein the first element and the second element are configured to be independently adjustable to increase the side-mode suppression ratio of the laser and the polarization-mode suppression ratio of the laser, respectively.

24. The laser of claim 23, wherein the active region comprises an active material, and wherein the second element is oriented along a direction of highest gain in the active material.

25. The laser of claim 23, wherein the laser has an inherent polarization plane due to spatial anisotropy, and wherein the second element is oriented along the inherent polarization plane.

26. The laser of claim 23, wherein the first element comprises a mode filter, and the second element comprises a polarization filter.

27. The laser of claim 23, wherein the first element comprises a mode filter, and the second element comprises an aperture.

28. The laser of claim 27, wherein the aperture has a cross-sectional area in a plane perpendicular to the optical axis, and wherein the cross-sectional area of the aperture defines a non-circular shape.

29. The laser of claim 28, wherein the mode filter has a cross-sectional area in the plane perpendicular to the optical axis, and wherein the cross-sectional area of the mode filter defines a non-circular shape.

30. The laser of claim 23, wherein the second element comprises a polarization filter and an aperture having a cross-sectional area in a plane perpendicular to the optical axis, and wherein the cross-sectional area of the aperture defines a non-circular shape.

31. The laser of claim 23, wherein the second element comprises a polarization filter and a mode filter having a cross-sectional area in a plane perpendicular to the optical axis, and wherein the cross-sectional area of the mode filter defines a non-circular shape.

32. The laser of claim 23, wherein the second element comprises:
a polarization filter;
a mode filter having a cross-sectional area in a plane perpendicular to the optical axis, wherein the cross-sectional area of the mode filter defines a non-circular shape; and
an aperture having a cross-sectional area in the plane perpendicular to the optical axis, wherein the cross-sectional area of the aperture defines a non-circular shape.

33. The laser of claim 23, wherein the second element comprises:
a mode filter having a cross-sectional area in a plane perpendicular to the optical axis, wherein the cross-sectional area of the mode filter defines a non-circular shape; and
an aperture having a cross-sectional area in the plane perpendicular to the optical axis, wherein the cross-sectional area of the aperture defines a non-circular shape.
